(19) United States
(12) Patent Application Publication
(10) Pub. No.: US 2012/0202697 A1
(43) Pub. Date: Aug. 9, 2012

(54) STIFFENED GRADIENT COIL

(76) Inventor: Simon James Calvert, Witney (GB)

(21) Appl. No.: 13/368,641

(22) Filed: Feb. 8, 2012

(30) Foreign Application Priority Data
Feb. 8, 2011 (GB) 1102154.0

(51) Int. Cl. H01F 6/06; H01F 6/04; G01R 33/3815

(52) U.S. Cl. 505/163; 505/211; 324/322

(57) ABSTRACT

In a cylindrical superconducting magnet system for magnetic resonance imaging, primary superconducting coils are positioned within an outer vacuum chamber. A thermal radiation shield surrounds the primary superconducting coils. A gradient coil assembly is axially aligned with the primary superconducting coils. A mechanical support assembly is radially positioned outside of the primary superconducting coils and is mechanically attached to the gradient coil assembly by mechanical attachments which pass through through-holes through the outer vacuum chamber and the thermal radiation shield.

### BACKGROUND

The present disclosure relates to cylindrical magnet systems as used in imaging systems such as MRI (Magnetic Resonance Imaging) systems.

FIG. 1 shows a radial cross-section through a typical magnet system for use in an imaging system. A cylindrical magnet 10, typically comprising superconducting coils mounted on a former or other mechanical support structure, is positioned within a cryostat, comprising a cryogen vessel 12 containing a quantity of liquid cryogen 15, for example helium, which holds the superconducting magnet at a temperature below its transition temperature. The magnet is essentially rotationally symmetrical about axis A-A. The term “axial” is used in the present document to indicate a direction parallel to axis A-A, while the term “radial” means a direction perpendicular to axis A-A. The cryogen vessel 12 is itself cylindrical, having an outer cylindrical wall 12a, an inner cylindrical bore tube 12b, and substantially planar annular end caps (not visible in FIG. 1). An outer vacuum container (OVC) 14 surrounds the cryogen vessel. It also is itself cylindrical, having an outer cylindrical wall 14a, an inner cylindrical bore tube 14b, and substantially planar annular end caps (not visible in FIG. 1). A hard vacuum is provided in the volume between the OVC 14 and the cryogen vessel 12, providing effective thermal insulation. A thermal radiation shield 16 is placed in the evacuated volume. This is typically not a fully closed vessel, but is essentially cylindrical, having an outer cylindrical wall 16a, an inner cylindrical bore tube 16b, and substantially planar annular end caps (not visible in FIG. 1). The thermal radiation shield 16 serves to intercept radiated heat from the OVC 14 before it reaches the cryogen vessel 12. The thermal radiation shield 16 is cooled, for example, by an active cryogenic refrigerator 17, or by escaping cryogen vapor.

In alternative arrangements, the magnet is not housed within a cryogen vessel, but is cooled in some other way: either by a low cryogen inventory arrangement such as a cooling loop, or a ‘dry’ arrangement in which a cryogenic refrigerator is thermally linked to the magnet. In these configurations, heat loads on the magnet are not directly deposited in the liquid cryogens but, instead, are indirectly removed via a thermal link connected to the cooling pipe or refrigerator. Such operational heat-loads can result, for instance, from current ramping or gradient coil operation.

The OVC bore tube 14b must be mechanically strong and vacuum tight, to withstand vacuum loading both radially and axially. Conventionally, it is made of stainless steel. The cryogen vessel bore tube 12b, if any, must be strong and capable of withstanding the pressure of cryogen gas within the cryogen vessel. Typically, this is also of stainless steel. The bore tube 16b of the thermal radiation shield 16 must be impervious to infra-red radiation. It is preferably lightweight. It is typically made of aluminum.

The present preferred embodiment may be applied in all such cases.

In order to provide an imaging capability, a set of gradient coils 20 are provided within the bore of the superconducting magnet. These are usually arranged as a hollow cylindrical, resin-impregnated block, containing coils which generate orthogonal oscillating magnetic field gradients in three dimensions.

During an imaging procedure, the gradient coils 20 generate rapidly oscillating magnetic fields with very fast rise-times of typically just a few milliseconds. Stray fields from the gradient coils generate eddy currents in metal parts of the cryostat, in particular in metal bore tubes 14b, 16b, 12b of OVC, thermal shield and cryogen vessel, and also in the structure of the magnet 10. The eddy currents produced in the material of the OVC 14 will help to shield the thermal radiation shield 16 and cryogenically cooled components such as cryogen vessel bore tube 12b, magnet coils and magnet former 10 from stray fields from the gradient coils 20. However, because of the constant background magnetic field produced by the magnet, those eddy currents produce Lorentz forces, acting radially and axially and resulting in mechanical vibrations in the bore tube of the OVC. Further mechanical vibrations result from mechanical vibration of the gradient coil assembly itself, caused by Lorenz forces acting on the conductors of the gradient coil assembly 20 which carry significant alternating currents. Mechanical vibration of the gradient coil assembly due to Lorenz forces acting on the conductors within the gradient coil assembly also causes noise by direct vibration of air within the bore.

These mechanical vibrations, in the constant background magnetic field of the magnet 10, will in turn induce secondary eddy currents in conductive materials, such as the bore tube 16b of the thermal radiation shield, or the bore tube 12b of a cryogen vessel. The secondary eddy currents will of course generate magnetic fields, known as secondary magnetic fields. These will interfere with imaging, and produce mechanical vibrations and secondary stray fields, which can be much larger than the stray fields produced by the gradient coils, in that region. The secondary stray fields also induce tertiary eddy currents in nearby conductive surfaces. These tertiary eddy currents will, in turn, generate tertiary magnetic fields, and so on.

The bore tube 16b of the thermal radiation shield 16 is preferably thermally and electrically conductive to provide electromagnetic shielding of the magnet from the gradient coils.

A particular difficulty arises when, as is typical, the frequency of oscillation of the gradient magnetic fields is close to the resonant frequency of the bore tubes. It is known that a number of concentric cross-tubes of similar diameters, such as the bore tubes of the OVC, thermal radiation shield and cryogen vessel of a typical MRI system, have similar effective resonant frequencies.

The mechanical vibrations will be particularly strong when a resonant vibration frequency of a bore tube corresponds to the frequency of oscillation of the stray field. If the resonant frequencies of the OVC bore tube, thermal shield bore tube, cryogen vessel bore tube if any, and magnet components are close together, as is the case in current magnets, the bore tubes behave as a chain of closely coupled oscillators, and resonance bands will occur.

The oscillations may also interfere with the imaging process, causing detriment to the resulting images.

The resulting oscillations cause acoustic noise which is most unpleasant for a patient in the bore, as well as interfering with imaging and causing heating of cooled components such as the thermal radiation shield and cryogen vessel, if any.

The eddy currents induced in the cryogenically cooled components of the magnet constitute an ohmic heat load on the cryogenic cooling system, leading to an increased consumption of liquid cryogen where used, or an increased heat load on the cryogenic refrigerator. In dry magnets—those which are not cooled by a liquid cryogen—the increased heat load can result in a temperature rise of the coils, which can result in a quench.

Known approaches to this problem include the following. The gradient coil assembly 20 may be mounted to the OVC bore tube 14b using resilient mounts, wedges or air bags. These are intended to attenuate the mechanical oscillations of the gradient coil assembly. However, such arrangements do not completely prevent mechanical transmission of vibrations from the gradient coil to the OVC, and do very little to reduce the incidence of eddy currents in adjacent electrically conductive structures. It has been suggested to mount the gradient coil on to end frames, rather than to the OVC bore tube. However, such arrangements have required a lengthening of the system, which the present preferred embodiment seeks to avoid. Mechanical stiffening of the gradient coil assembly has been attempted. However, it is believed that a doubling of the stiffness of the gradient coil assembly will only result in an approximately 1.4×increase in the resonant frequency. Active force feedback actuators are suggested in U.S. Pat. No. 6,552,543, where actuators are placed within the OVC to oppose vibrations caused by stray fields from gradient coils. This solution is considered complex, and difficult to position the actuators between other components such as the magnet coils. Mode-compensated gradient coils have been suggested, in which primary and secondary conductors of the gradient coil assembly itself are optimized to reduce the amplitude of vibration of the gradient coil assembly. However, such optimization has been found to increase the stray field strength of the gradient coil assembly, resulting in increased heating of cryogenically cooled components due to eddy current generation.

Known approaches to similar problems have been set out in the following publications.

U.S. Pat. No. 6,552,543 B1 (Dietz et al., Siemens) discloses the use of mountings, including active mounts, between the gradient coil assembly and the cryostat.

U.S. Pat. No. 5,345,177 B2 (Sato et al, Hitachi) this discloses the use of radial-spoke gradient coil mountings incorporating soft pads.

U.S. Pat. No. 6,353,319 B1 (Dietz et al., Siemens) discloses mounting the gradient coil in the magnet bore, at points of maximum amplitude of mechanical vibrations, to disrupt resonant modes.

U.S. Pat. No. 7,053,744 B2 (Arz et al., Siemens) discloses a vacuum enclosure for the gradient coil.

U.S. Pat. No. 5,617,026 (Yoshino et. al, Hitachi) discloses the use of Piezo-transducers as a means of reducing the amplitude of gradient vibrations.

DE 10 2007 025 096 A1 (Dietz et al., Siemens) discloses a method of mode-compensation of a gradient coil.

### SUMMARY

It is an object to reduce the oscillation of bore tubes subjected to oscillating gradient coil magnetic fields.

In a cylindrical superconducting magnet system for magnetic resonance imaging, primary superconducting coils are positioned within an outer vacuum chamber. A thermal radiation shield surrounds the primary superconducting coils. A gradient coil assembly is axially aligned with the primary superconducting coils. A mechanical support assembly is radially positioned outside of the primary superconducting coils and is mechanically attached to the gradient coil assembly by mechanical attachments which pass through through-holes through the outer vacuum chamber and the thermal radiation shield.

### BRIEF DESCRIPTION OF THE DRAWINGS

The above, and further, objects, characteristics and advantages of the present preferred embodiment will become more apparent from the following description of certain embodiments thereof, given by way of examples only, with reference to the accompanying drawings.

FIG. 1 shows a radial cross-section of a typical magnet system for use in an imaging system; and

FIGS. 2-7 show schematic partial cross-sectional views of exemplary embodiments of the present invention.

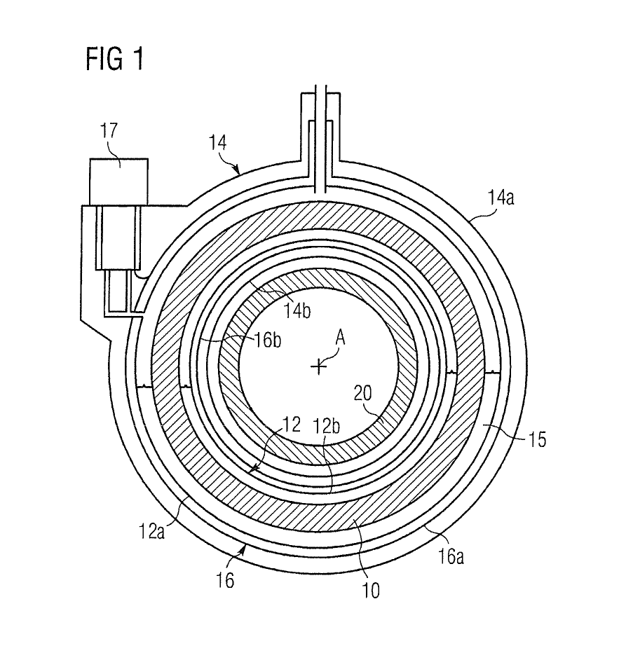

### DESCRIPTION OF THE PREFERRED EMBODIMENTS

For the purposes of promoting an understanding of the principles of the invention, reference will now be made to the preferred exemplary embodiments/best mode illustrated in the drawings and specific language will be used to describe the same. It will nevertheless be understood that no limitation of the scope of the invention is thereby intended, and such alterations and further modifications in the illustrated embodiments and such further applications of the principles of the invention as illustrated as would normally occur to one skilled in the art to which the invention relates are included.

A rigid mechanical support is provided for the gradient coil assembly, positioned radially outside of the gradient coil assembly, superconducting magnet coils and the OVC and thermal radiation shield. The gradient coil assembly is mechanically joined to the mechanical support, which provides increased mechanical stiffness of the primary coil assembly. This, in turn, reduces mechanical vibration of the gradient coil assembly, leading to a reduction in acoustic noise from the gradient coil assembly, reduced eddy currents induced in nearly conductive surfaces, and thus reduced heating of cryogenically cooled components.

The present preferred embodiment provides arrangements in which mechanical vibration of the gradient coil, and gradient coil induced heating (GCIH) resulting from operation of the gradient coil are significantly reduced. Significantly, the present preferred embodiment allows the reduction in mechanical vibration and GCIH to be achieved without reducing the available radial diameter of the bore of the gradient coil assembly, without increasing the diameter of superconducting coils and without increasing the length of the magnet system.

The present exemplary embodiment provides an arrangement for restraining mechanical vibration of the gradient coil assembly, and reducing transmission of mechanical vibrations from the gradient coil assembly to other components of the magnet system.

The axial ends of the cryostat are most susceptible to stray magnetic gradient fields. In some embodiments, mechanical support structures are provided only near axial ends of the cryostat. In addition, these ‘end supports’ do not significantly contribute to the stiffness of the gradient coil itself.

It is important to keep the bore of the gradient coils as open as possible, as that determines the diameter of the patient bore. Reduction in the diameter of the patient bore would result in reduced comfort for the patient, possibly resulting in spoiled imaging sequences, or patients being unable or unwilling to be imaged, due to the restricted volume available.

It is important to keep the length of the magnet system as short as possible, as an increase in length may increase or induce feelings of claustrophobia in patients, which may spoil imaging sequences, or cause patients to refuse to be imaged. Shorter magnets also require less space during transport and on site at the user's premises. The length of a magnet system is commonly used as a selling point, with shorter magnets being regarded as more desirable.

According to the present exemplary embodiment, a combination of features allows the objects of the exemplary embodiment to be achieved.

A radially outer mechanical support structure is provided, mechanically linked to the gradient coil assembly, but mechanically isolated from the cryostat.

The gradient coil structure is mechanically isolated from the cryostat structure to avoid mechanical excitation of vibrations in the OVC by mechanical vibrations of the gradient coil assembly. In certain embodiments of the present invention, the gradient coil is supported directly on the floor, having no contact with the cryostat structure.

Those parts of the OVC bore tube which are most subject to gradient coil stray fields—typically near the bore tube ends—are stiffened or made of an electrically non-conductive material to reduce or eliminate the effects of eddy currents and secondary stray fields.

According to a feature of the present preferred embodiments, a mechanical gradient coil assembly support is provided, radially outside of the gradient coil assembly and primary superconducting coils.

In some embodiments of the present invention, the gradient coil assembly is enclosed within the OVC, to prevent transmission of acoustic noise from the gradient coil assembly.

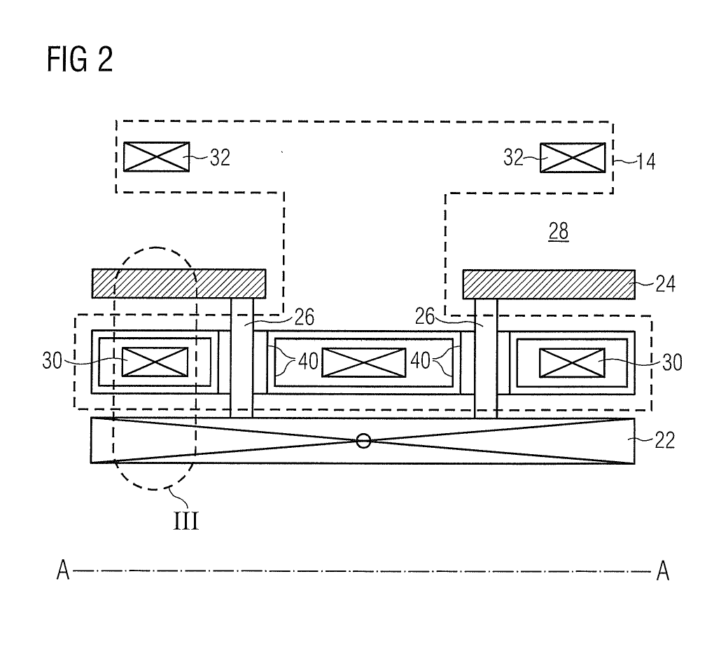

FIG. 2 schematically illustrates a partial axial cross-section of a general gradient coil assembly according to an embodiment of the present invention, comprising a gradient coil assembly 22 and a gradient coil assembly support 24. The structure of FIG. 2 is essentially rotationally symmetrical about axis A-A. The gradient coil assembly 22 and the mechanical support 24 are not mechanically linked to the remainder of the structure. The mechanical gradient coil support 24, in this example, comprises two annular structures, each positioned radially outside the gradient coil assembly near axial ends thereof. Each annular structure is mechanically attached 26 to the gradient coil assembly 22.

In this arrangement, OVC 14, shown dotted in the drawing, has an annular re-entrant portion defining a recess 28 in each annular end-cap. This re-entrant portion may usefully increase the stiffness of the end-cap, reducing its tendency to vibrate during imaging operations. The annular structures of the mechanical support 24 are located within this re-entrant portion. The superconducting magnet comprises primary superconducting coils 30, positioned within the OVC, radially inside the recess 28 and shield coils 32 positioned within the OVC, radially outside the recess 28. The shield coils 32 and primary coils 30 are mechanically supported and joined in any appropriate manner. The manner of mechanical support and joining of the primary superconducting coils and the secondary, shield, superconducting coils does not form part of the present preferred embodiment, other than in that the mechanical attachments 26 linking the gradient coil assembly 22 to the mechanical support 24 pass though through-holes through the OVC, thermal radiation shield and any structure supporting and joining the primary coils 30 and the secondary, shield, coils 32.

The through-holes in the OVC and thermal radiation shield must of course be sealed with cross-tubes 40. In some embodiments, it may be found that the additional stiffness introduced by the presence of these cross-tubes 40 enables thinner materials to be used for the OVC and thermal shields, possibly enabling the diameter of the bore of the magnet, and so also of the gradient coil assembly, to be increased.

During imaging, the currents in the gradient coils are rapidly pulsed. The rapidly changing currents in the gradient coils, flowing in the background magnetic field of the superconducting coils 30, cause Lorenz forces to act on the gradient coil assembly and tend to cause mechanical vibrations. The present preferred embodiment aims to reduce these mechanical vibrations by increasing the stiffness of the gradient coil assembly, using a radially outer mechanical support structure.

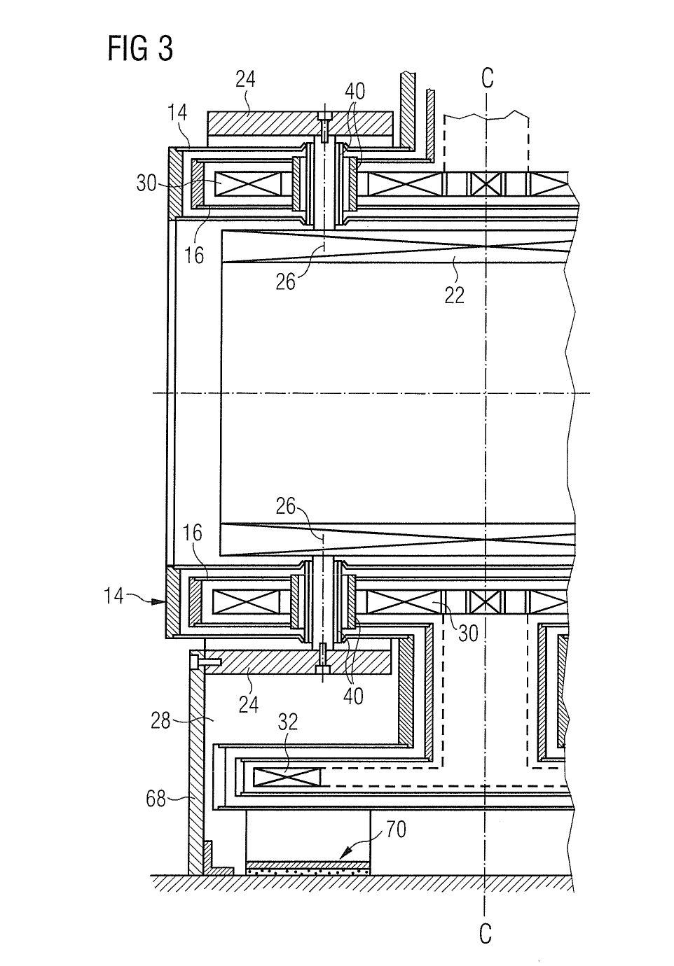

FIG. 3 shows a more complete partial axial cross-section of an embodiment of the present invention resembling the example shown in FIG. 2. The structure in FIG. 3 is essentially rotationally symmetrical about axis A-A, and essentially has reflectional symmetry about the centre plane marked C-C.

Cross-tubes 40 allow mechanical supports 26 to pass through the OVC 14 and the thermal radiation shield 16, while ensuring the functional integrity of both the OVC and the thermal radiation shield, yet avoiding any mechanical contact between the gradient coil assembly and the OVC.

Coils 30 of the primary superconducting magnet are mechanically supported and retained in required fixed relative positions by any suitable arrangement which allows cross-tubes 40 to pass radially between coils.

Superconducting shield coils 32 are mechanically supported and retained in position by any suitable arrangement which allows the provision of a re-entrant portion defining cavity 28 in the annular end caps of the OVC, sufficient for placement of secondary gradient coil assemblies 24.

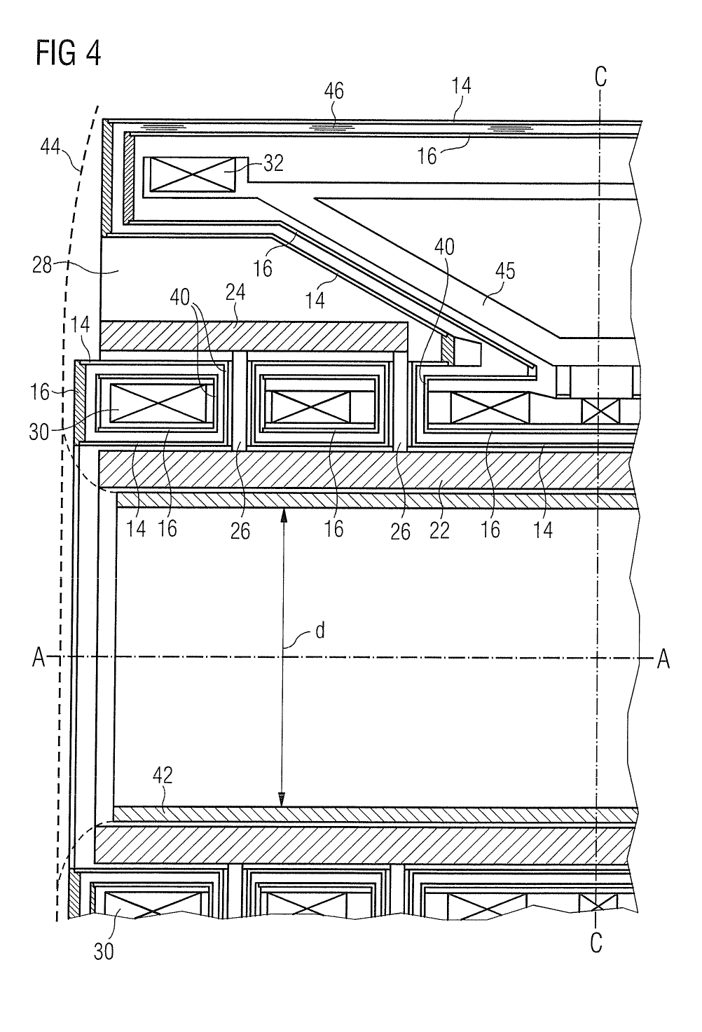

FIG. 4 illustrates another example embodiment of the present invention, similar to that of FIG. 3, having two sets of mechanical supports 26 at each axial end of the OVC bore tube. An example of a suitable mechanical support structure 45 is illustrated in FIG. 4, but others may be employed as preferred, within the scope of the present invention.

A body coil 42 is illustrated in this embodiment, provided within the gradient coil assembly. Body coils will similarly be provided in the other illustrated embodiments, but are not shown for clarity of illustration. The body coil, in use, provides an RF (radio-frequency) oscillating magnetic filed, as required for magnetic resonance imaging. The inner diameter d of the body coil defines the patient bore: the cavity into which a patient must enter to be imaged. It is desired that the advantages of the present embodiments should be achieved without the need to reduce the inner diameter of the patient bore.

Looks covers, shown dotted at 44, are used to cover the ends of the magnet system, and present an aesthetically pleasing, easy-to-clean, outer surface.

The support structure 45 of the superconducting shield coils 32 is such that a re-entrant portion may be provided in the end caps of the OVC 14, thermal radiation shield 16 and cryogen vessel, if any. Accordingly, an essentially annular cavity 28 is defined in the end caps of the OVC.

As illustrated in FIG. 4, the gradient coil support structure 24 is positioned within the recess 28. In this embodiment, as in FIGS. 2-3, an annular structure is provided within the recess 28 near each axial end of the OVC bore tube. Mechanical supports 26 pass through cross-tubes 40 and link the gradient coil assembly 22 with the mechanical support structure 24. The annular rings of the mechanical support structure 24 are placed in a volume conventionally within the OVC. The provision of mechanical support structure 24 does not reduce the available patient bore diameter d as compared to a similar magnet system with a conventional gradient coil arrangement.

The mechanical support structure 24 restricts movement and flexure of the gradient coil assembly by increasing the effective rigidity of the gradient coil assembly. This reduction in movement leads to reduced eddy currents in adjacent conductive surfaces, reduced acoustic noise within the patient bore, and reduced gradient coil induced heating of cryogenically cooled components.

Although not illustrated, conventional mechanical support arrangements may be provided to suspend the magnet assembly, the thermal radiation shield and the cryogen vessel, if any, within the OVC 14. Any suitable mechanical arrangement may be provided for supporting and retaining coils 30 of the primary superconducting magnet in position. Solid thermal insulation 46, for example aluminized polyester sheets, may be provided between the thermal radiation shield 16 and the OVC 14, as is conventional.

The presence of radially-directed cross-tubes 40 through axially-outer parts of the OVC 14 and thermal radiation shield 16 which house the primary superconducting magnet significantly increase the stiffness of the OVC and thermal radiation shield in those regions, which are the regions most susceptible to stray gradient magnetic fields. The added stiffness of OVC and thermal radiation shield reduce the amplitude of vibrations induced by eddy currents on the respective bore tubes, reducing the associated heating. The reduced amplitudes of vibration also reduce the amplitude of secondary eddy currents. The re-entrant end cap of the OVC reduces the magnitude of vibration of the end cap.

The gradient coil assemblies are directly supported on the floor. The length is increased but only at the lower part of the bore, not around the entire circumference. This is not an issue as the ‘open viewing angle’ for the patient is not affected and the length of the main part of the bore is what would be quoted in the spec. All conventional systems also have longer bore length at the bottom due to the presence of the patient table.

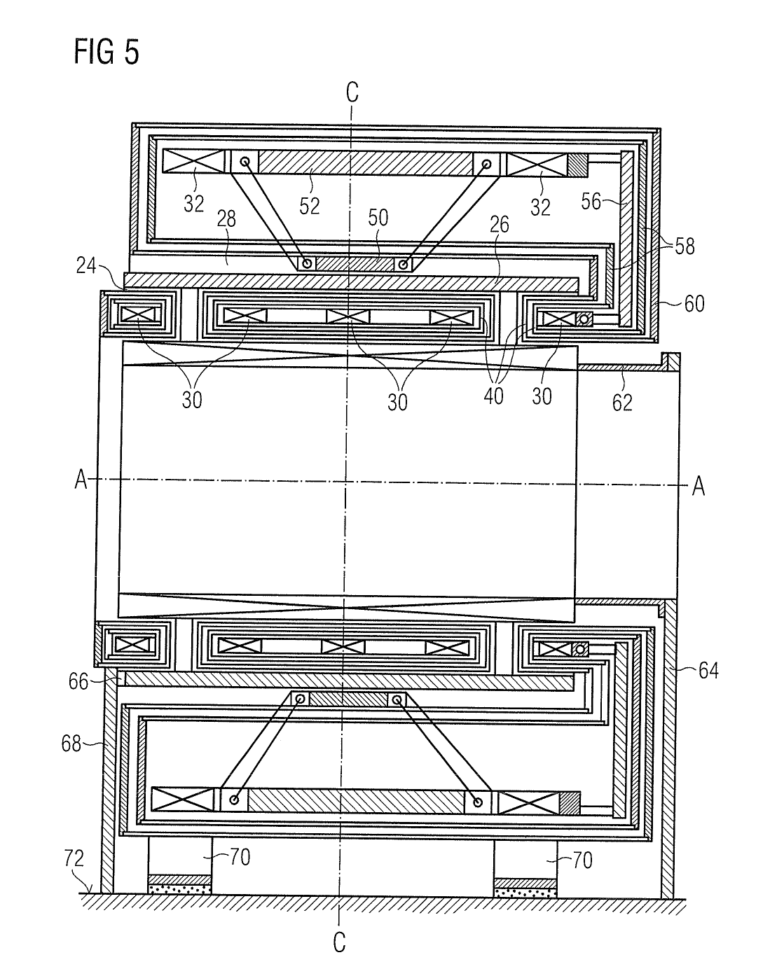

FIG. 5 illustrates a further embodiment of the present invention. This embodiment requires extra length of the system, but only at the non-patient end, so again the patient experience is unaffected. In this embodiment, one OVC end cap is provided with a fully re-entrant portion, so that the annular recess 28 extends at least to the distal axial end of the mechanical support structure 24. Gradient coil assembly 22 is shown, in this case extending the length of the primary superconducting coil 30 assembly. Cross-tubes 40 are provided, similar to those shown in FIG. 4, which define through-holes through a part of the OVC 14 and thermal radiation shield 16 which houses the primary superconducting coils. The primary superconducting coils 30 are retained together and supported in such a way that the cross-tubes 40 may pass through the associated parts of the OVC 14 and thermal radiation shield 16 without touching the primary superconducting coil assembly.

The mechanical support structure 24 for the gradient coil assembly is provided within the recess 28. As the recess extends axially the length of the primary gradient coil assembly, a single tubular structure may be provided, extending axially the length of the primary gradient coil assembly, and mechanically attached 26 to the gradient coil assembly 24 at at least two axial positions, either side of centre line C-C, each preferably near an axial end of the primary gradient coil assembly. The resultant mechanically supported gradient coil assembly is very rigid, and the additional rigidity is provided without reduction in the available bore of the magnet system.

In the illustrated embodiment, due to the axial length of the recess 28, the secondary, shield, superconducting coils 32 are not directly mechanically supported on the primary superconducting coil assembly. Rather, an intermediate support piece 50 is provided, mechanically attached, and sealed to the OVC. This support piece is a strong annular structure, and the secondary, shield, superconducting coils 32 are mounted on a mechanical support structure 52 which is supported on the support piece 50, itself supported on the OVC.

At the axial end of the magnet structure away from the recess 28, the secondary, shield, superconducting coils 32 are mechanically connected to the primary magnet coils 30 by an annular magnet connection structure 56, at the operating temperature of the coils. Annular parts 58 of the thermal radiation shield 16, and annular parts 60 of the OVC 24 enclose the annular magnet connection structure 56, and complete the thermal radiation shield and OVC respectively.

The gradient coil assembly is supported by an annular extension piece 62 which is attached to the gradient coil assembly 22 and extends axially out of the bore of the OVC. A ground support 64 supports the gradient coil assembly on a support surface 72, typically the ground, using the annular extension piece 62.

Alternatively, or in addition, an annular extension piece 66 may be attached to the tubular structure of the mechanical support 24 and extend axially out of the recess 28 of the OVC end piece. A ground support 68 may then support the gradient coil assembly and mechanical support assembly 24 on the support surface 72, using the annular extension piece 66. Feet 70 support the OVC on the support surface 72.

This embodiment is believed to provide a stiffer gradient coil assembly than embodiments such as shown in FIG. 4, where two separate annular structures are provided, towards opposite axial ends of the primary gradient coil assembly.

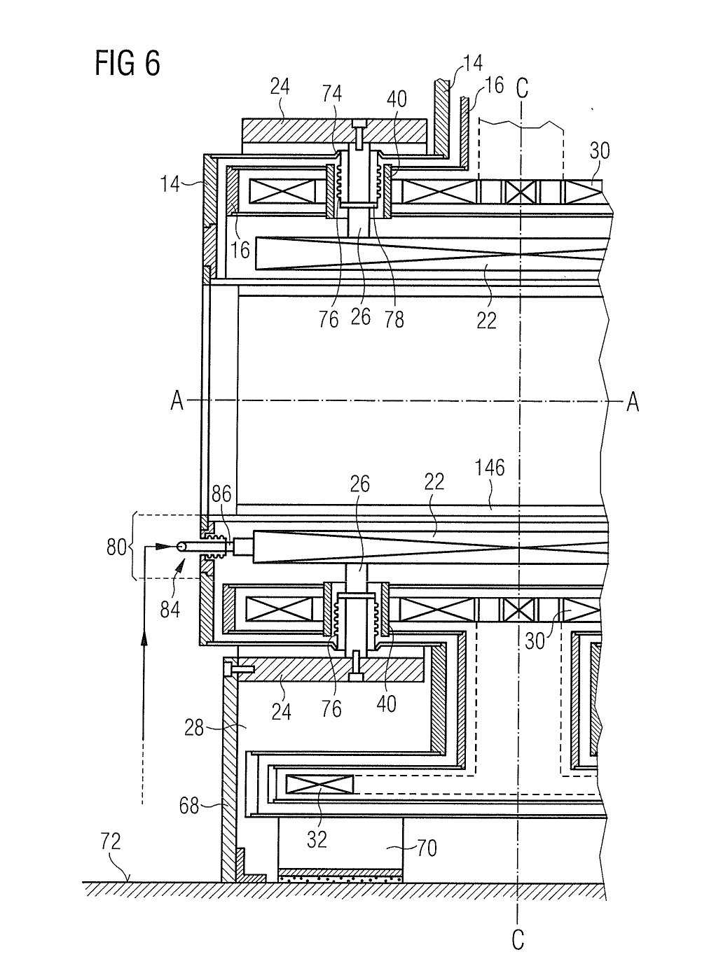

A further embodiment of the present invention is shown in FIG. 6. In this embodiment, the gradient coil assembly 22 is positioned within the OVC, in the evacuated space between the OVC 14 and the thermal radiation shield 16. By positioning the gradient coil assembly in the vacuum space, no acoustic noise can propagate from it. Mechanical support assembly 24 is positioned outside of the OVC, in the annular recess 28 described with reference to earlier embodiments. Mechanical support assembly 24 is supported on a support surface 72, typically the ground, by ground support 68. The gradient coil assembly 22 is mechanically supported by the mechanical support structure 24 through mechanical supports 26. In this embodiment, the mechanical supports pass through cross-tubes 40 within the thermal radiation shield 16, as in other embodiments described above. However, supports 26 must pass from outside the OVC, where they interface with the mechanical support assembly 24, to within the OVC, where they interface with the gradient coil assembly 22.

In the illustrated embodiment, this is arranged by providing holes 74 in the OVC surface between the gradient coil assembly 22, and the mechanical support assembly 24, and closing those holes with bellows arrangements 76, in this example each being closed by a closure member 78 sealed to the mechanical support 26. The bellows arrangements 76 allow the OVC to remain vacuum-tight, while absorbing mechanical vibrations from the gradient coil assembly and ensuring that these mechanical vibrations are not applied to the OVC.

Preferably, a part 80 of the end cap of the OVC is removable, to allow placement and replacement of the gradient coil 22. Of course, the part 80 can only be removed when the OVC is not evacuated. The presence of removable part 80 is of significant assistance when the OVC is being assembled around the primary superconducting coils 30. Preferably, in such arrangements, the OVC bore tube 14b is of an electrically non-conducting, non-magnetic material. An example of a suitable material is glass fiber impregnated with thermosetting resin. Such material does not suffer from eddy current generation, and is magnetically transparent so that is does not interfere with the gradient magnetic fields generated by the gradient coils. In such an arrangement, the OVC bore tube 14b will not suffer from Lorenz forces.

In order to provide the required electrical current to the gradient coil assembly, at least one current lead-through 84 is provided in the OVC, preferably in the removable part 80. The current lead-through is preferably connected to the OVC with a bellows 86 which serves to isolate the OVC from any mechanical vibration of the gradient coil assembly, while still enabling the OVC to remain vacuum-tight. The bellows may be closed by a closure member sealed to the current lead-through.

The gradient coil will heat up to ˜80K and this will impose an increased heat-load on the thermal shield and therefore, indirectly, the magnet. However, this ‘steady-state’ heat-load is believed tolerable given that the much more severe dynamic element is much reduced due to the extensive stiffening. This arrangement is the ultimate in acoustic noise reduction since all known transmission methods are eliminated or considerably reduced.

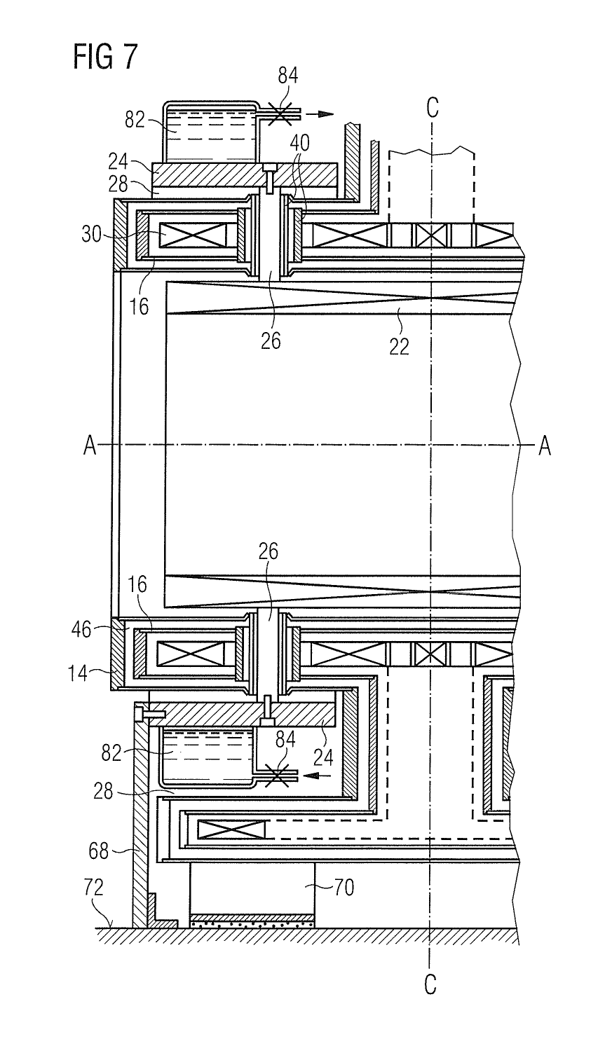

FIG. 7 shows an improvement to the embodiment of FIG. 3. An inertial damper, preferably an annular water-filled chamber 82, is attached to the annular structure of the mechanical support assembly 24. This adds significant mass and inertia to the mechanical support assembly. Preferably, the chamber 82 is empty for shipping, but is filled with water through one or more of valves 84, while air is allowed to escape from at least one other of the valves 84, at the site where the magnet system is installed. If required, for example for further transport, the water may be emptied, and air admitted, once again through valves 84. Of course, liquids other than water may be used to fill the chamber 82; and loose material such as sand or fine gravel may be used instead of a liquid. However, water is presently preferred as it is plentiful, inexpensive, non-toxic and easy to dispose of.

Although shown with specific reference to the embodiment of FIG. 3, the filled chamber 82 of FIG. 8 may be applied to any embodiment of the present invention. In some embodiments, the annular chamber need not extend fully around the annular structure of the mechanical support assembly, although it is preferred that it does.

The present exemplary embodiments accordingly provide gradient coil arrangements in an imaging system, in which oscillation of the OVC, thermal radiation shield, and cryogen vessel, are significantly reduced. This improves the resultant imaging and patient comfort.

According to the present exemplary embodiments, flexural stiffness of the gradient coil is increased by mechanically linking the conventional gradient coil assembly to a radially outer mechanical support assembly 24 by mechanical supports 26. The resultant mechanical stiffening reduces the amplitude of any vibrations and increases the resonant frequencies of the gradient coil assembly towards values which are not excited by normal imaging sequences. As a result, the gradient coil induced heating of the magnet is much reduced which, in particular, is of great benefit for a minimum cryogen inventory or cryogen-free magnet.

The gradient coil structure is mechanically isolated from the cryostat structure to avoid direct mechanical excitation of vibrations in the OVC. Preferably, the gradient coil assembly is mounted to a support surface independently of the cryostat structure.

The parts of the OVC and thermal radiation shield near the axial ends of the bore are preferably stiffened to reduce the amplitude of any vibration. This stiffening may be achieved by fitting of cross-tubes 40 as described above, which allow mechanical supports 26 to pass from the gradient coil assembly 22 to the mechanical support assembly 24. The axial ends of the OVC and thermal radiation shields generally experience stronger stray magnetic fields from the gradient coil assembly than the axial centers of the bore tubes of the OVC and the thermal radiation shield. These axially outer parts of the OVC may be made of a composite material such as glass fibre impregnated with thermosetting resin, to prevent eddy current generation in the material of the OVC.

According to an aspect of an exemplary embodiment, the Lorentz forces within the gradient coil assembly are resisted by the increased mechanical rigidity provided by the attachment of the gradient coil assembly to the mechanical support assembly 24.

In certain embodiments of the invention, the primary gradient coil assembly is enclosed in a vacuum space within the OVC to eliminate any pressure-based noise transmission.

Preferably, the objects of the exemplary embodiments are achieved without increasing the length of the bore of the OVC or the gradient coil assembly of the system, and without reducing the diameter d of the available patient volume. Indeed, due to the stiffening effect of the OVC and thermal radiation shield cross-tubes 40, the thickness of the bore tube of the OVC and thermal radiation shield bore tube can be reduced, which may increase the diameter of the available patient volume.

In an alternative embodiment the gradient coil assembly and the mechanical support assembly are mechanically linked together outside of the OVC and thermal radiation shield—for example by an annular support ring axially outside of the primary superconducting coils and OVC. This arrangement does not strengthen the OVC and thermal radiation shield so much at the ends, but allows the use of a more conventional cryostat configuration without transverse penetrations.

Although preferred exemplary embodiments are shown and described in detail in the drawings and in the preceding specification, they should be viewed as purely exemplary and not as limiting the invention. It is noted that only preferred exemplary embodiments are shown and described, and all variations and modifications that presently or in the future lie within the protective scope of the invention should be protected.

I claim as my invention:

1. A cylindrical superconducting magnet system for use in magnetic resonance imaging, comprising:
axially aligned primary superconducting coils positioned within an outer vacuum chamber;
a thermal radiation shield surrounding the primary superconducting coils within the outer vacuum chamber;
a gradient coil assembly axially aligned with the primary superconducting coils and located radially within the primary superconducting coils;
a mechanical support assembly radially positioned outside of the primary superconducting coils and mechanically attached to the gradient coil assembly; and
the mechanical support assembly being mechanically attached to the gradient coil assembly by mechanical attachments which pass through through-holes through the outer vacuum chamber and the thermal radiation shield.

2. A cylindrical superconducting magnet system according to claim 1 wherein the mechanical attachments pass between adjacent primary superconducting coils.

3. A cylindrical superconducting magnet system according to claim 1 wherein the through-holes in the outer vacuum chamber are sealed by radially-directed tubes extending between a bore tube of the outer vacuum chamber and the recess, and in which the mechanical attachments pass through the tubes.

4. A cylindrical superconducting magnet system according to claim 3 wherein the through-holes in the thermal radiation shield are sealed by radially-directed tubes extending coaxially with the tubes sealing the outer vacuum chamber.

5. A cylindrical superconducting magnet system according to claim 1 wherein the mechanical support assembly comprises two annular structures, each mechanically attached to the gradient coil assembly near axial extremities thereof.

6. A cylindrical superconducting magnet system according to claim 1 wherein the mechanical support assembly comprises a tubular structure mechanically attached to the gradient coil assembly on both sides of an axial mid-plane thereof.

7. A cylindrical superconducting magnet system according to claim 1 wherein the outer vacuum chamber and its contents are supported on a support surface, and the gradient coil assembly and the associated mechanical support assembly are supported on the support surface independently of the outer vacuum chamber and its contents.

8. A cylindrical superconducting magnet system according to claim 1 further comprising a cryogen vessel housing the primary superconducting coils such that the thermal radiation shield surrounds the cryogen vessel within the outer vacuum chamber.

9. A cylindrical superconducting magnet system according to claim 6 wherein the outer vacuum chamber comprises a bore tube, an outer cylindrical wall and annular end pieces, one of the end pieces having a re-entrant portion defining a recess, and the tubular structure being positioned within the recess.

10. A cylindrical superconducting magnet system according to claim 5 wherein the outer vacuum chamber comprises a bore tube, an outer cylindrical wall and annular end pieces, both end pieces having a respective re-entrant portion defining a respective recess, and a respective annular structure is positioned within each recess.

11. A cylindrical superconducting magnet system according to claim 6 wherein secondary shield superconducting coils are provided radially outside of the primary superconducting coils and the tubular structure, an intermediate support piece being provided mechanically attached and sealed to the outer vacuum chamber, the secondary shield superconducting coils being mounted on a further mechanical support structure which is supported on the support piece, and also being mechanically supported on the outer vacuum chamber.

12. A cylindrical superconducting magnet system according to claim 11 wherein at an axial end of the magnet structure away from the cavity, the secondary shield superconducting coils are mechanically connected to the primary magnet coils by an annular magnet connection structure; annular parts of the thermal radiation shield, and annular parts of the outer vacuum chamber enclose the annular magnet connection structure and complete the thermal radiation shield and outer vacuum chamber respectively.

13. A cylindrical superconducting magnet system according to claim 1 wherein the gradient coil assembly is connected to the mechanical support assembly outside of the outer vacuum chamber and the thermal radiation shield.

14. A cylindrical superconducting magnet system according to claim 13 wherein the mechanical support assembly comprises an annular support ring positioned axially outside of the primary superconducting coils and the outer vacuum chamber.

15. A cylindrical superconducting magnet system according to claim 1 wherein the mechanical support assembly includes a chamber which, in use, is filled with a liquid or loose material to provide mass and inertia to the mechanical support assembly.
